(19) United States
(12) Patent Application Publication
(10) Pub. No.: US 2010/0150255 A1
(43) Pub. Date: Jun. 17, 2010

(54) Semiconductor integrated circuit including transmitter and receiver which conducts loopback test and test method thereof

(75) Inventors: Shinya Konishi, Kanagawa (JP); Norio Arai, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/591,931

(22) Filed: Dec. 4, 2009

(30) Foreign Application Priority Data
Dec. 17, 2008 (JP) 2008-321128

(51) Int. Cl. H04L 7/00; H03D 3/24; H04L 27/00

(52) U.S. Cl. 375/259; 375/376; 375/356

(57) ABSTRACT

A semiconductor integrated circuit includes an oscillation circuit for generating multiple clocks of mutually different phases, and is also characterized in selecting a single clock FCLK_P from among multiple clocks FCLK_P [n-1:0] for use in transmitting IQ Serial transmission signals and, utilizing the FCLK_P to transmit an IQ Serial transmission signal.

### INCORPORATION BY REFERENCE

This application is based upon and claims the benefit of priority from Japanese Patent Application No. 2008-321128 which was filed on Dec. 17, 2008, the disclosure of which is incorporated herein in its entirety by reference.

### BACKGROUND OF THE INVENTION

1. Field of the Invention

The present invention relates to a semiconductor integrated circuit and to a test method for that circuit.

2. Description of Related Art

One example of an operation test of a receive circuit mounted in a semiconductor circuit is disclosed in patent document (Japanese Patent Application Laid Open No. 2006-303786) The data transmit-receive circuit disclosed in patent document makes the serial transmission data loop back to the receive circuit to test the receive circuit.

FIG. 8 is a block diagram that shows the structure of the data transmit-receive circuit disclosed in patent document. As shown in the figure, the data transmit-receive circuit 41 contains a phase adjuster unit 400 for separately aligning the rising-edge phase and falling-edge phase of the serial data SData received from the serializer 61, on the loopback path 80 that conveys the received the serial data SData generated by the serializer 61 making up the transmit circuit unit 60 to the receive circuit unit 70. FIG. 9 is a drawing showing the structure of the phase adjuster unit 400. As shown in the figure, the phase adjuster unit 400 contains a delay circuit 410 made up of multiple delay cells 411 for delaying the serial data SData by an optional delay quantity; and a duty ratio change circuit 420 for changing the duty ratio of the serial data SData. The phase adjuster unit 400 delays the serial data SData by utilizing the multiplexer 412 to select the delay circuit 410. The duty ratio change circuit 420 changes the high and the low sections of the serial data SData or in other words changes the duty ratio. FIG. 10 shows the structure of the delay cells 411. As shown in the figure, the delay cell 411 is made up of two NAND gates 411a and 411b. FIG. 11 is a drawing showing the structure of the duty ratio change circuit 420. As shown in the figure, the duty ratio change circuit 420 contains the first through fifth inverter devices, and nMOS transistors to turn the respective inverter devices on and off. The first inverter device for example is made up of a pMOS transistor 421a and an nMOS transistor 421b. Here, the nMOS transistor that turns the first inverter device on and off is nMOS transistor 421c. The duty ratio change circuit 420 receives an output signal from the multiplexer 412, and uses the external duty ratio change signals TR<0> to TR<3> to set one or more of the nMOS transistors 421b to 424b having differing size ratios to the active state, and changes the duty ratio by way of an output from the output buffer.

### SUMMARY

The data transmit-receive circuit in patent document however utilizes multiple gates as shown in FIG. 9 through FIG. 11 as the method for aligning the phase of the serial transmission data and therefore requires a structure for making analog alignments. The data transmit-receive circuit in patent document 1 in other words makes analog type changes to serial transmission data waveform degradation.

This method therefore has the problem that when temperature or production conditions have changed during the semiconductor circuit test, the analog components are drastically affected causing a change in their operation making it impossible to perform a stable quantitative evaluation. For example when making an evaluation test of semiconductor circuits, the tests are always made at a fixed delay (quantity) so that the delay (quantity) must be reset for each LSI being tested, which so that the test program cannot run efficiently.

A semiconductor integrated circuit of an exemplary aspect according to the present invention includes an oscillation circuit for generating multiple clocks possessing mutually different phases. The semiconductor integrated circuit selects a single clock from among the multiple clocks to use for sending the transmission signal and utilizes that single clock to send the transmission signal.

By guaranteeing the phase difference among the multiple clocks generated by the oscillation circuit, and selecting a single clock from among those multiple clocks for sending the transmission signal, the test method for semiconductor integrated circuit of the present invention can make an efficient and stable quantitative evaluation without being affected by the semiconductor integrated circuit production conditions or other factors.

The test method for semiconductor integrated circuits of the present invention includes an oscillation circuit for generating multiple clocks of mutually different phases, a transmit circuit for sending the transmission signal, and a receive circuit for receiving the transmission signal sent by the transmit circuit during the loopback test operation and is characterized by a step for selecting a single clock from the multiple clocks for use in sending the transmit signal, and for sending that transmission signal by utilizing the selected clock, and a step for performing the received processing signal by utilizing the multiple clocks.

The test method for the semiconductor integrated circuit of the present invention guarantees the phase differences among the multiple clocks generated by the oscillation circuit, and by selecting and utilizing a single clock from among these multiple clocks to use in sending the transmission signal, can constantly obtain transmission signals received at the receive circuit at a fixed delay quantity and therefore make an efficient and stable quantitative evaluation without being affected by the semiconductor integrated circuit production conditions or other factors.

The semiconductor integrated circuit and the test method of the present invention can therefore provide a test method and semiconductor integrated circuit capable of making efficient and stable quantitative evaluations.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a drawing showing the structure of the semiconductor integrated circuit of a first exemplary embodiment of the present invention;

FIG. 2 is a drawing showing the structure of the transmit circuit (TX) of the first exemplary embodiment of the present invention;

FIG. 3 is a graph for describing the operation for generating the IQ Serial (data signal) by the transmit circuit (TX) of the first exemplary embodiment of the present invention;

FIG. 4 is a drawing showing the structure of the receive circuit (RX) of the first exemplary embodiment of the present invention;

FIG. 5 is a drawing showing the structure of the transmit circuit (TX) of a second exemplary embodiment of the present invention;

FIG. 6 is a graph for describing the operation for generating the IQ Serial (data signal) by the transmit circuit (TX) of the second exemplary embodiment of the present invention;

FIG. 7 is drawings for describing the effect of the exemplary embodiments of the present invention;

FIG. 8 is a drawing for describing a related technology;

FIG. 9 is a drawing for describing the related technology;

FIG. 10 is a drawing for describing the related technology;

FIG. 11 is a drawing for describing the related technology.

### DETAILED DESCRIPTION OF THE EXEMPLARY EMBODIMENTS

### First Exemplary Embodiment

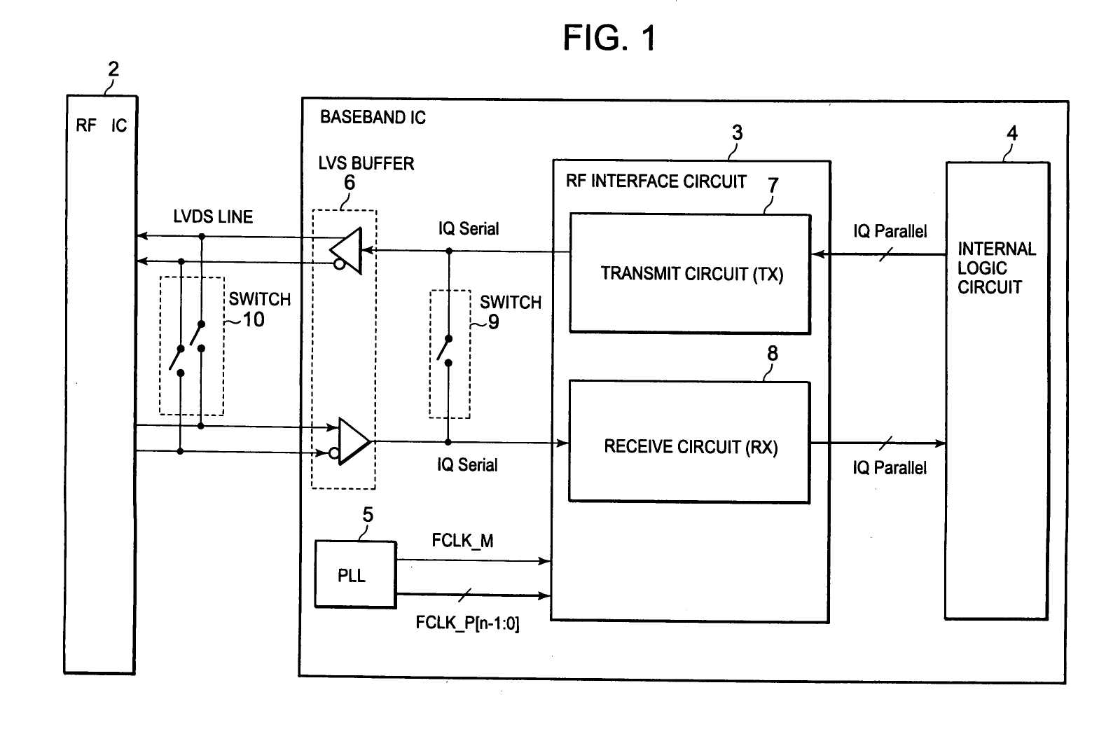

FIG. 1 illustrates a structure of the semiconductor integrated circuit (more specifically, a baseband IC) of a first exemplary embodiment of the present invention. During normal operation, when not making a loopback test as shown in FIG. 1, the semiconductor integrated circuit 1 exchanges (sends and receives) transmission signals with the other device 2 (specifically an RF IC) over an LVDS line for low-voltage differential signaling (LVDS). Here, the semiconductor integrated circuit 1 is the LSI device for testing. During the loopback test operation, the semiconductor integrated circuit 1 is tested by making a self-loopback test using transmission signals that are sent back from the semiconductor integrated circuit 1 itself without using the other device 2.

The semiconductor integrated circuit 1 contains an RF interface circuit 3, an internal logic circuit 4, a PLL (Phase Locked Loop) circuit 5, and LVDS buffer 6 made up of an LVDS circuit, and a switch 9. The RF interface circuit 3 is an interface for carrying out clock-less, high-speed synchronous communication, and includes a transmit circuit (TX) 7, and a receive circuit (RX) 8. The transmit circuit (TX) 7, and a receive circuit (RX) 8 are described in detail later on.

The internal logic circuit 2 generates processing data (IQ Parallel) processed within the system and outputs it to the transmit circuit (TX) 7. The data signal IQ Parallel is for example parallel data with a bit width of 8 bits. The internal logic circuit 2 performs signal processing (for example, decoding including a path search of receive data) based on the parallel data IQ Parallel output from the receive circuit (RX) 8, and generates data signals or control signals utilized in latter stage circuits (not shown in drawings).

The PLL circuit 5 generates a standard clock FCLK_M and a multiphase clock FCLK_P [n-1:0]. The PLL circuit 5 outputs the generated standard clock FCLK_M and a multiphase clock FCLK_P [n-1:0] to the RF interface circuit 3. In the first exemplary embodiment, the standard clock FCLK_M and a multiphase clock FCLK_P [n-1:0] are high-speed clocks obtained by frequency-multiplication of the reference clocks. It is noted that n is natural number, for example. The multiphase clock FCLK_P [n-1:0] consists of multiple clocks at the same speed and possessing mutually different phases of 360°/n each; The n as described in the first exemplary embodiment is 8. The output from the PLL circuit 5 therefore consists of a bit width of one bit, and a bit width of eight bits, and each bit corresponds to a single clock phase.

The LVDS buffer 6 preferably converts the transmission signal (IQ Serial) sent from the transmit circuit (TX) 7, to a low voltage differential signaling (LVDS) serial signal. The LVDS buffer 6 preferably converts the transmission signal (IQ Serial) sent to the receive circuit (RX) 8 to a low voltage differential signaling (LVDS) serial signal. Here, the data signal IQ Serial is serial data. The serial transmission signal from the transmit circuit (TX) 7 for example is differentially amplified by the LVDS buffer 6 and sent as shown in FIG. 1. The differentially amplified signal is sent along two LVDS lines, and each signal line conveys the transmission signal and an inverted transmission signal. In this way, even when transmitting and receiving data at high speed using a low-voltage transmission signal, the resistance to noise can be enhanced by transmitting the differential signal for the two signals.

In the first exemplary embodiment, the semiconductor integrated circuit 1 contains a switch 9, and a switch 10 between the semiconductor integrated circuit 1 and the other device 2. A loopback test can in this way be made on the semiconductor integrated circuit 1 by setting the switch 9 to ON. The semiconductor integrated circuit 1 and the other device 2 mounted on the substrate can be made to perform the loopback test by turning the switch 9 to OFF and the switch 10 to ON. Utilizing the switch 10 allows sending and receiving the transmission signals between the transmit circuit (TX) 7 and the receive circuit (RX) 8 by way of the LVDS buffer 6 during the loopback test so that a test of the LVDS buffer 6 can be made at the same time.

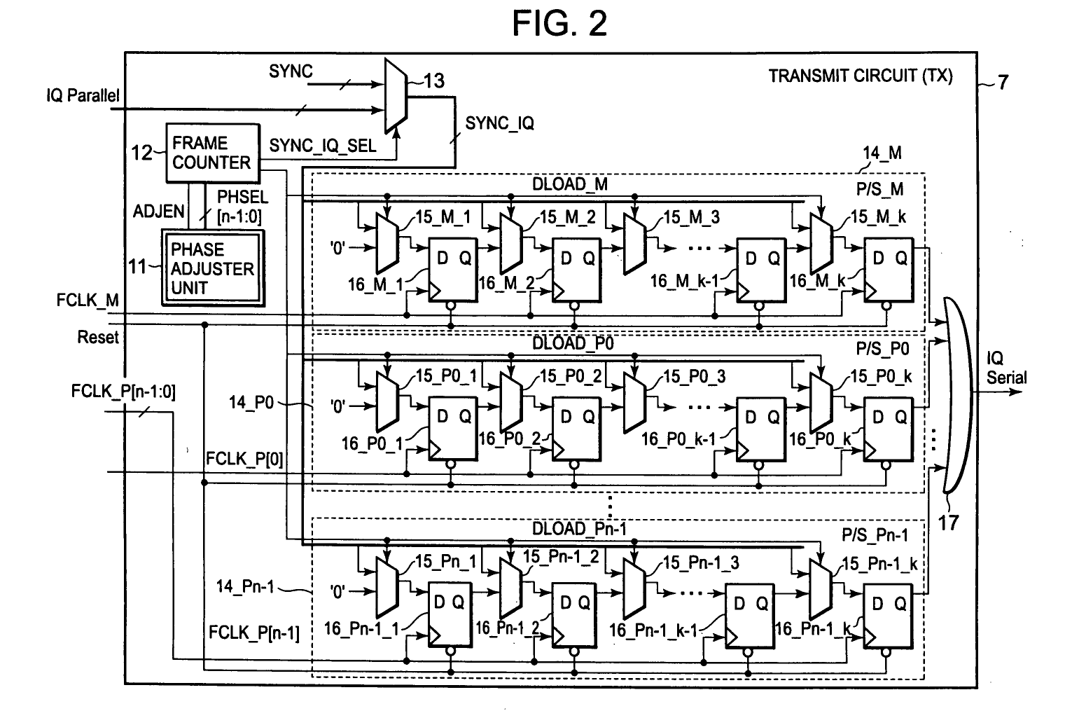

The structure of the transmit circuit (TX) 7 of the first exemplary embodiment is described next while referring to FIG. 2. The transmit circuit (TX) 7 is synchronized with the standard clock FCLK_M during normal operation and generates an IQ Serial. During the loopback test, the transmit circuit (TX) 7 synchronizes with a single clock FCLK_P selected from among the multiphase clock FCLK_P [n-1:0] and generates IQ Serial (data signal). The transmit circuit (TX) 7 sends the generated IQ Serial to the receive circuit (RX) 8.

The transmit circuit (TX) 7 as shown in FIG. 2 contains an phase adjuster unit 11, a frame counter 12, a selector 13, a parallel-serial converter (P/S) 14_M, a parallel-serial converter (P/S) 14_P0 to parallel-serial converter (P/S) 14_Pn-1, and an OR circuit 17.

The phase adjuster unit 11 selects a single clock FCLK_P from among the multiphase clocks FCLK_P [n-1:0]. This phase adjuster unit 11 switches the test operation. The phase adjuster unit 11 is for example a register. A test operation switching signal ADJEN and a clock select signal PHSEL [n-1:0] are set within the phase adjuster unit 11. The phase adjuster unit 11 outputs the ADJEN signal for example shows 1 during loopback test operation and outputs an ADJEN signal for example showing 0 during normal operation. One example of the clock select signal PHSEL [n-1:0] may be the signal (PHSEL7, PHSEL6, PHSEL5, . . . , PHSEL0)=(0, 0, 0, 0, 0, 0, 0, 1). The bit farthest to the left on the bit string indicates the MSB (Most Significant Bit) and the bit farthest to the right indicates the LSB (Least Significant Bit). This example shows the first clock FCLK_P0 counting from the LSB was selected. The test operation switching signal ADJEN and a clock select signal PHSEL [n-1:0] may be set based on the specified signal from the internal logic circuit 4, or may be set by the tester performing the test.

In the first exemplary embodiment, the transmit circuit (TX) 7 here places the IQ Parallel (data) generated here by the internal logic circuit 4 in a frames format and sends it as the transmission signal. The transmission signals now in a frame format are in the sync word area and the payload area contained within the data string. The system sends the payload following the synch word. The IQ Parallel generated in the internal logic circuit 4 is input to the transmit circuit (TX) 7 as shown in FIG. 2, and input to the selector 13 of transmit circuit (TX) 7. The synch word (Hereafter, abbreviated simply to “Sync”.) made by the system is input to the selector 13 as parallel data. The Sync is set for example in a register (not shown in drawing) formed in the transmit circuit (TX) 7.

The frame counter 12 estimates the frame start position based on the packet length of the frame, and outputs a select signal SYNC_IQ_SEL for switching between the SYNC data section and the IQ data section. The selector 13 selects the data signal based on the select signal SYNC_IQ_SEL and, outputs the selected data signal as parallel data (SYNC_IQ) to the parallel-serial converter (P/S) 14_M, and parallel-serial converter (P/S) 14_P0 through parallel-serial converter (P/S) 14_Pn-1.

The frame counter 12 outputs the control signal DLOAD_M, the control signals DLOAD_P0 through control signals DLOAD_Pn-1 to each of the parallel-serial converters (P/S). The control signal DLOAD_M, and the control signals DLOAD_P0 through control signals DLOAD_Pn-1 signify signals that allow each parallel-serial converter (P/S) to load the SYNC_IQ. A single signal among the control signal DLOAD_M, and the control signals DLOAD_P0 through control signals DLOAD_Pn-1 operate exclusively as the data load signal. The frame counter 12 sets the control signal DLOAD_M, and control signals DLOAD_P0 through control signals DLOAD_Pn-1 based on the test operation switching signal ADJEN and the clock select signal PHSEL [n-1:0]. During the loopback test operation, the frame counter 12 constantly outputs 0 from the DLOAD_M signal and the DLOAD_P signal corresponding for example to the clocks that were not selected; and also outputs a control signal only from the DLOAD_P signal corresponding to the selected clock. During normal operation, the frame counter 12 outputs a control signal only from the DLOAD_M signal, and also outputs 0 from the DLOAD_P signal corresponding to the multiphase clock.

The parallel-serial converter (P/S) 14_M operates in synchronization with the standard clock FCLK_M. The parallel-serial converter (P/S) 14_P0 through parallel-serial converter (P/S) 14_Pn-1 operate in synchronization with the respective multiphase clocks FCLK_P [n-1:0]. Namely, each of the parallel-serial converters (P/S) synchronizes with the respectively supplied clock to convert the loaded parallel data (SYNC_IQ) to serial data (SYNC_IQ). The OR circuit 17 logically sums the output from each parallel-serial converter (P/S), and this output from OR circuit 17 is output as IQ Serial.

The parallel-serial converter (P/S) 14_M and parallel-serial converters (P/S) 14_P0 through parallel-serial converters (P/S) 14_Pn-1 contain multiple selectors and multiple flip-flops. The parallel-serial converter (P/S) 14_M for example contains the selectors 15_M_1 through selectors 15_M_k, and the flip-flops 16_M_1 through flip-flops 16_M_k. Each of the data contained in the SYNC_IQ is respectively input to the selectors 15_M_1 through selector 15_M_k. Also, the control signals DLOAD_M are respectively input to the selectors 15_M_1 through selector 15_M_k. These selectors 15_M_1 through selectors 15_M_k select the input data signals based on the control signals DLOAD_M, and output the selected data signals respectively to the flip-flops 16_M_1 through flip-flops 16_M_k. The standard clock FCLK_M is supplied respectively to the flip-flops 16_M_1 through flip-flops 16_M_k, and these flip-flops 16_M_1 through flip-flops 16_M_k then operate synchronously with the standard clock FCLK_M. A Reset signal is input to the flip-flops 16_M_1 through flip-flops 16_M_k and inputting this Reset signal clears the values in the flip-flops.

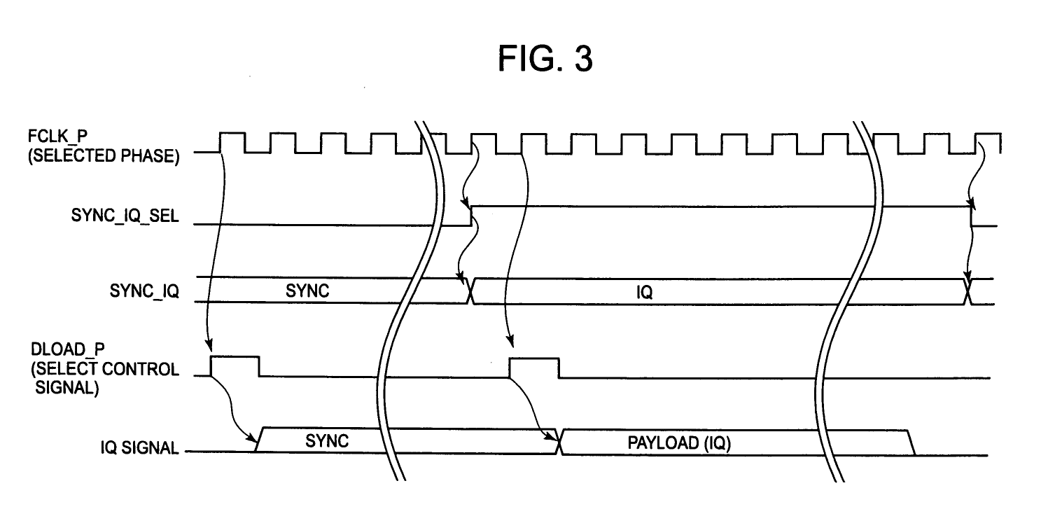

The operation state in which the transmit circuit (TX) 7 generates the IQ Serial is described here while referring to FIG. 3. Here, FIG. 3 is a drawing for describing the operation state where receive circuit (TX) 7 generates the IQ Serial (signals) synchronously with the clock FCLK_P selected by the clock select signal PHSEL [n-1:0]. As shown in the figure, the selector 13 based on the SYNC_IQ_SEL, first of all synchronizes with the clock FCLK_P and selects the SYNC and IQ Parallel that were input to the selector 13 and outputs them as the SYNC_IQ. The parallel-serial converter (P/S) 14_P then synchronizes with the clock FCLK_P and captures the SYNC_IQ at the control signal DLOAD_rise timing. The parallel-serial converter (P/S) 14_P that captured the SYNC_IQ, synchronizes with the clock FCLK_P, and then outputs the IQ Serial by sequentially outputting the data respectively latched in the flip-flops 16_P_1 through flip-flops 16_P_k. The transmit circuit (TX) 7 in this way converts the parallel data (IQ Parallel) synchronized with the single clock selected by the phase adjuster unit 11, to the serial data (IQ Serial).

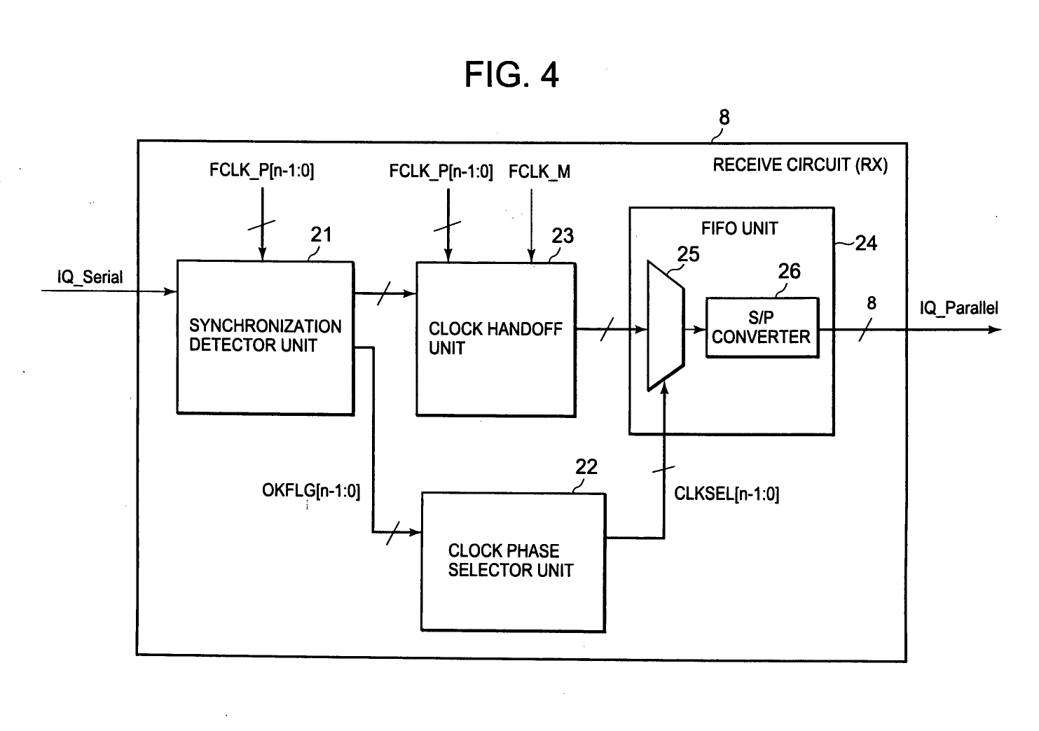

The structure of the receive circuit (RX) 8 of the first exemplary embodiment is described next while referring to FIG. 4. The receive circuit (RX) 8 synchronizes with the multiphase clock FCLK_P [n-1:0] and performs receive processing of the transmission signal sent from the other device 2 or the transmit circuit (TX) 7. The receive circuit (RX) 8 contains a synchronization detector unit 21, a clock phase selector unit 22, a clock handoff unit 23, and an FIFO unit 24.

The synchronization detector unit 21 receives the transmission signals at multiple clocks of mutually different phases. The synchronization detector 21 then samples the sync (synchronization) words serving as the synchronized information contained in the received transmission signal at the multiple clocks of mutually different phases, and compares the sampling results with a pre-established synchronization pattern. If there is a clock corresponding to the synchronization pattern and matching synchronized word, then the clock at that sampling is identified from among the multiple clocks as the selected candidate clock. The synchronization detector 21 in other words, samples the synch (synchronization) words input at n number of clocks FCLK_P [n-1:0] of mutually different phases. The synchronization detector 21 outputs to the clock phase selector unit 22, OKFLG [n-1:0] as a signal showing at which clock among n number of clocks of different phases, the pre-established synchronization pattern was correctly sampled. The OKFLG [n-1:0] for example becomes a bit 1 signal for a clock where the pre-established synchronization pattern was correctly sampled; and becomes a bit 0 signal for clocks where the applicable synchronization pattern was not correctly sampled.

The clock phase selector unit 22 selects a single clock for use in sampling the transmission signal from among the clocks FCLK_P [n-1:0] that sampled synchronization word matching the synchronization pattern. More specifically, the clock phase selector unit 22 receives the output signal OKFLG [n-1:0] from the synchronization detector 21 and selects a single clock for use in sampling from among the multiple FCLK_P [n-1:0]. The clock phase selector unit 22 outputs the select signal CLKSEL [n-1:0] indicating the selected clock, to the selector 25 of FIFO unit 24. The select signal CLKSEL [n-1:0] is a parallel signal indicating the output from the clock phase selector unit 22. The select signal CLKSEL [n-1:0] is transmitted in parallel by way of n number of signal lines. The clock selected for sampling for example is indicated by 1, and clocks not selected for sampling are indicated by 0. In one possible case for example, the clock phase selector unit 22 may select a single phase clock FCLK_P [n-1:0] from among eight phase clocks FCLK_P [n-1:0] and receive a signal (OKFLG7, OKFLG6, OKFLG5, . . . , OKFLG0)=(0, 1, 1, 1, 1, 1, 0, 0) as the output signal OKFLG [n-1:0] from the synchronization detector 21. The clock phase selector 22 may in this case select the clock FCLK_P4 for safe sampling in the center among the selectable clocks FCLK_P2 through 6. The clock phase selector 22 may then output (CLKSEL7, CLKSEL6, CLKSEL5, . . . , CLKSEL0)=(0, 0, 0, 1, 0, 0, 0, 0) as the select signal CLKSEL [n-1:0]. The bit on the left end is the most significant bit (MSB), and indicates whether or not the clock FLCK_P7 input to the synchronization detector 21 was selected. The bit on the right end is the least significant bit and indicates whether or not the clock FCLK_P0 input to the synchronization detector 21 was selected. In other words, in this example the clock phase selector 22 selects 1 which is the fifth bit counting from the LSB so that the clock phase selector 22 selects the clock FCLK_P4 input to the synchronization detector 21. This result indicates that the selector 25 will be operated by the clock FCLK_P4 which is the fifth bit counting from the LSB.

The clock handoff unit 23 receives the data signal output from the synchronization detector 21 at the clock FCLK_P [n-1:0] and performs asynchronous handoff processing to handoff the received data signal to the standard clock FCLK_M. A circuit in a latter stage after (downstream) the clock handoff unit 23 is operated at a single phase of the phase standard clock FCLK_M. In contrast, a circuit in a stage prior (upstream) to the clock handoff unit is operated at the multiphase clock FCLK_P [n-1:0] so that the clock handoff unit 23 performs the asynchronous handoff processing to the standard clock FCLK_M.

The FIFO unit 24 contains a selector 25, and a serial-parallel converter (S/P converter) 26. The selector 25 selects the data signal output by the clock handoff unit 23 based on the select clock CLKSEL [n-1:0], and outputs the selected data to the S/P converter 26. The S/P converter 26 synchronizes the serial data sampled in the FIFO unit 24, with the internal circuit standard clock SCLK, and converts it to parallel data (IQ Parallel) and outputs it.

In the semiconductor integrated circuit of the first exemplary embodiment described above, the PLL circuit 5 guarantees the phase difference between the sampling clocks utilizing the clock in transmit processing by the transmit circuit (TX) 7 and the sampling by the receiver circuit (RX) 8. By then using a single clock selected from the sampling clocks for generating the timing of serial transmit data sent by the transmit circuit (TX), a fixed delay can be constantly obtained without sustaining effects caused by production variations in the semiconductor integrated circuit 1. A quantitative clock evaluation can therefore be made with the clock operating the receive circuit (RX) 8 and the testing can be performed with more stability and efficiency.

### Second Exemplary Embodiment

The semiconductor integrated circuit (more specifically the baseband IC) of the second exemplary embodiment is described next. The semiconductor integrated circuit of the second exemplary embodiment differs from the semiconductor integrated circuit 1 of the first exemplary embodiment only in the transmit circuit (TX). Therefore only the structure and operation of the transmit circuit of the second exemplary embodiment are described next, and a description of the structure and operation where identical to the first exemplary embodiment is omitted.

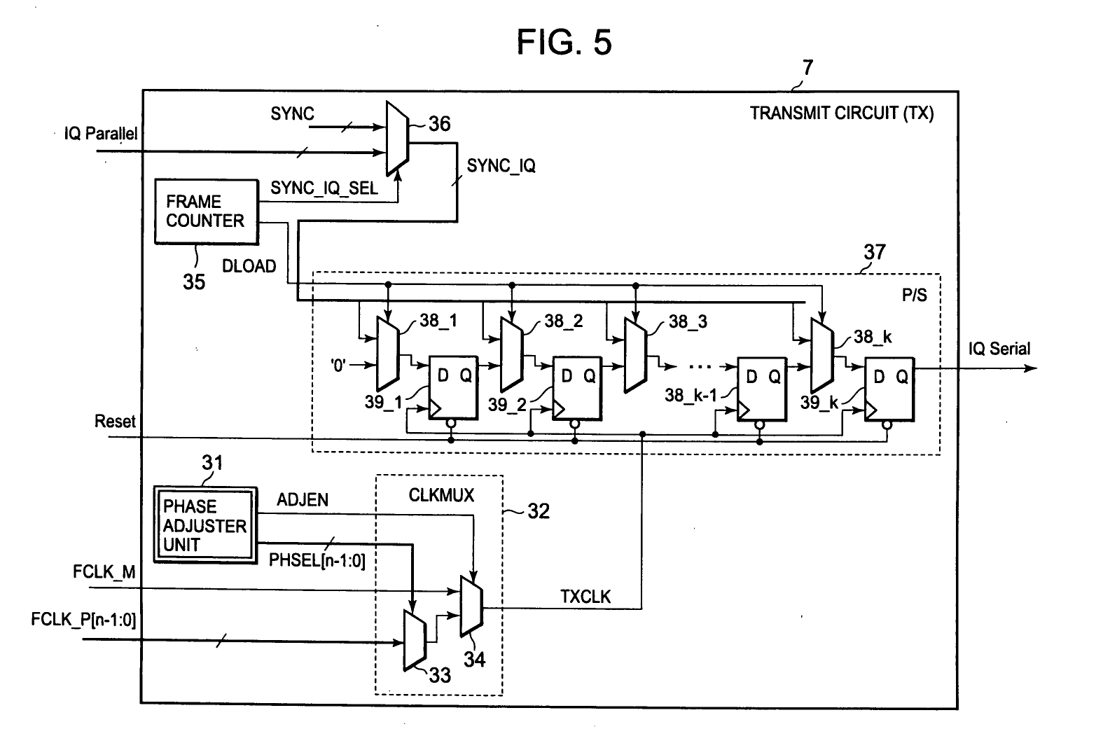

FIG. 5 is a circuit diagram showing the structure of the transmit circuit (TX) 7 of the second exemplary embodiment. During normal operation, the transmit circuit (TX) 7 generates IQ Serial (data signals) in synchronization with the standard clock FCLK_M. During loopback test operation, the transmit circuit (TX) 7 generates IQ Serial (data signals) in synchronization with the single clock FCLK_P selected from the multiphase clock FCLK_P [n-1:0]. The transmit circuit (TX) 7 sends the generated IQ serial (data signals) to the receive circuit (RX) 8.

The transmit circuit (TX) 7 as shown in FIG. 5, includes a phase adjuster unit 31, a clock selector (CLKMUX) 32, a frame counter 35, a selector 36, and a parallel-serial converter (P/S) 37.

The phase adjuster unit 31 selects a single clock FCLK_P from the multiphase clock FCLK_P [n-1:0] to select. The phase adjuster unit 31 also switches the test operation. The structure of the phase adjuster unit 31 is for example a register. The test operation switching signal ADJEN and the clock select signal PHSEL [n-1:0] are set within the phase adjuster unit 31. During the loopback test, the phase adjuster unit 31 outputs an ADJEN signal for example indicating 1, and during normal operation outputs an ADJEN signal for example indicating 0. Moreover, one possible example of a clock select signal PHSEL [n-1:0] is (PHSEL7, PHSEL6, PHSEL5, . . . , PHSEL0)=(0, 0, 0, 0, 0, 0, 0, 1) signal. The bit farthest to the left on the bit string indicates the MSB (Most Significant Bit) and the bit farthest to the right indicates the LSB (Least Significant Bit). This example shows that the first clock FCLK_P0 counting from the LSB was selected. The test operation switching signal ADJEN and a clock select signal PHSEL [n-1:0] may be set based on the specified signal from the internal logic circuit 4, or may be set by the tester performing the test.

The clock selector (CLKMUX) 32 is made up of a selector 33 and a selector 34. The selector 33 selects a single clock from the multiphase clock FCLK_P [n-1:0].

The selector 34 outputs a single clock from the clocks selected by the standard clock FCLK_M and the selector 33, based on the test operation switching signal and outputs that single clock as TXCLK.

In this second exemplary embodiment, the transmit circuit (TX) 7 here also changes the IQ Parallel (data) generated by the internal logic circuit 4 into a frames format and sends it as the transmission signal. The transmission signals now in a frame format are in the sync word area and the payload area contained within the data string. The system sends the payload following the synch word. The IQ Parallel (data) generated in the internal logic circuit 4 is input to the transmit circuit (TX) 7 as shown in FIG. 5, and then input to the selector 36 within the transmit circuit (TX) 7. The synch word section (Hereafter, abbreviated simply to “Sync”.) established by the system is input to the selector 36 as parallel data. The Sync is set for example in a register (not shown in drawing) formed in the transmit circuit (TX) 7.

The frame counter 35 estimates the frame start position based on the packet length of the frame, and outputs a select signal SYNC_IQ_SEL that switches between the SYNC data section and the IQ data section. The selector 36 selects the data signal based on the select signal SYNC_IQ_SEL and, outputs the selected data signal as parallel data (SYNC_IQ) to the parallel-serial converter (P/S) 37.

The frame counter 35 outputs the control signal DLOAD to the parallel-serial converter (P/S) 37 so that the parallel-serial converter (P/S) 37 can load the SYNC_IQ.

The parallel-serial converter (P/S) 37 operates in synchronization with the clock TXCLK that was selected by the clock selector (CLKMUX) 32. The parallel-serial converter (P/S) 37 in other words synchronizes with the supplied clock TXCLK and converts the loaded parallel data (SYNC_IQ) to serial data (SYNC_IQ). The parallel-serial converter (P/S) 37 outputs the converted serial data as IQ serial (data signal).

The parallel-serial converter (P/S) 37 contains the selectors 38_1 through selectors 38_k, and the flip-flops 39_1 through flip-flops 39_k. The parallel-serial converter (P/S) 37 inputs each of the data contained in the SYNC_IQ respectively to the selectors 38_1 through selectors 38_{—}k. Also, the control signal DLOAD is respectively input to the selectors 38_1 through selectors 38_{—}k. The selectors 38_1 through selectors 38_{—}k select the data signals that were input based on the control signal DLOAD, and output the signal data respectively to the flip-flops 39_1 through flip-flops 39_{—}k. The clock TXCLK is supplied to the flip-flops 39_1 through flip-flops 39_{—}k, and these flip-flops 39_1 through flip-flops 39_{—}k operate in synchronization with this clock TXCLK. A Reset signal is input to the flip-flops 39_1 through flip-flops 39_{—}k, and inputting this Reset signal clears the values in the flip-flops.

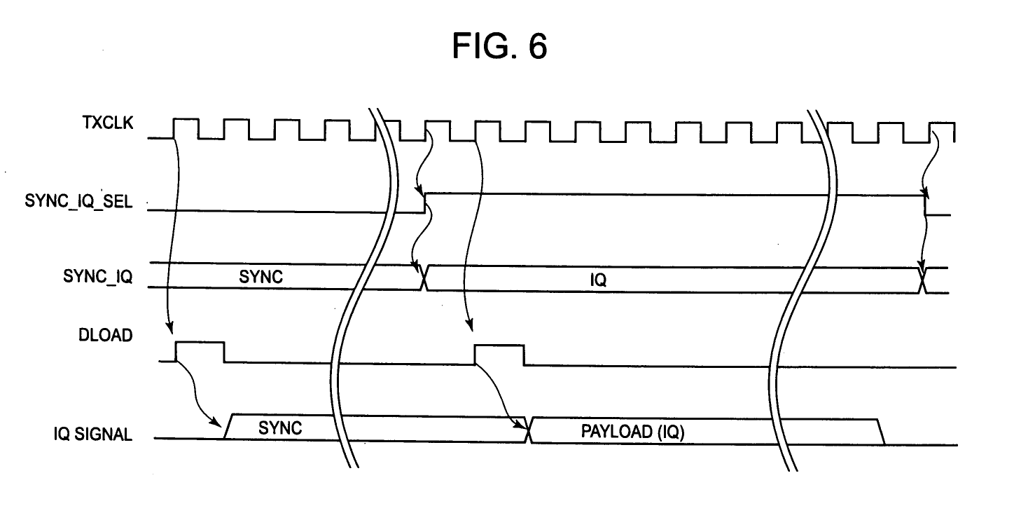

The operation state in which the transmit circuit (TX) 7 generates the IQ Serial (data signal) is described here while referring to FIG. 6. Here, FIG. 6 is a drawing for describing the operation state of the receive circuit (TX) 7 when generating the IQ Serial (signals) based on the SYNC and IQ Parallel in synchronization with the selected clock TXCLK based on PHSEL [n-1:0]. As shown in the figure, the clock selector (CLKMUX) 32 first of all selects the clock TXCLK based on the clock select signal PHSEL [n-1:0] and the test operation switching signal ADJEN. The selector 36 operating in synchronization with the selected clock TXCLK, selects the SYNC and IQ Parallel that were input to the selector 36 based on the SYNC_IQ_SEL and outputs them as the SYNC_IQ. The parallel-serial converter (P/S) 37 then synchronizes with the clock TXCLK and captures the SYNC_IQ at the rising edge timing of the control signal DLOAD. The parallel-serial converter (P/S) 37 that captured the SYNC_IQ, synchronizes with the clock TXCLK, and then outputs the IQ Serial (signal) by sequentially outputting the data respectively latched in the flip-flops 39_1 through flip-flops 39_{—}k. The transmit circuit (TX) 7 in this way converts the parallel data (IQ Parallel) synchronized with the single clock selected by the phase adjuster unit 31, to the serial data (IQ Serial).

In the semiconductor integrated circuit of the second exemplary embodiment described above, the PLL circuit 5 guarantees the phase difference between the sampling clocks utilizing the clock in transmit processing by the transmit circuit (TX) 7 and the sampling clock by the receiver circuit (RX) 8. By then using the single clock selected from the sampling clocks for generating the timing of serial transmit data sent by the transmit circuit (TX), a fixed delay (quantity) can be constantly obtained without sustaining effects caused by production variations in the semiconductor integrated circuit 1. A quantitative clock evaluation can therefore be made with the clock operating the receive circuit (RX) 8, and the testing can be performed with more stability and efficiency.

In the transmit circuit (TX) 7 of the second exemplary embodiment, the phase adjuster unit 31 selects a single clock TXCLK from among multiple clocks, and operates one of the serial-parallel converters (P/S) 37 while switching the selected clock so that unlike the transmit circuit 7 of the first exemplary embodiment, multiple parallel-serial converters are not required, and a further increase in the circuit scale of the transmit circuit (TX) 7 is prevented.

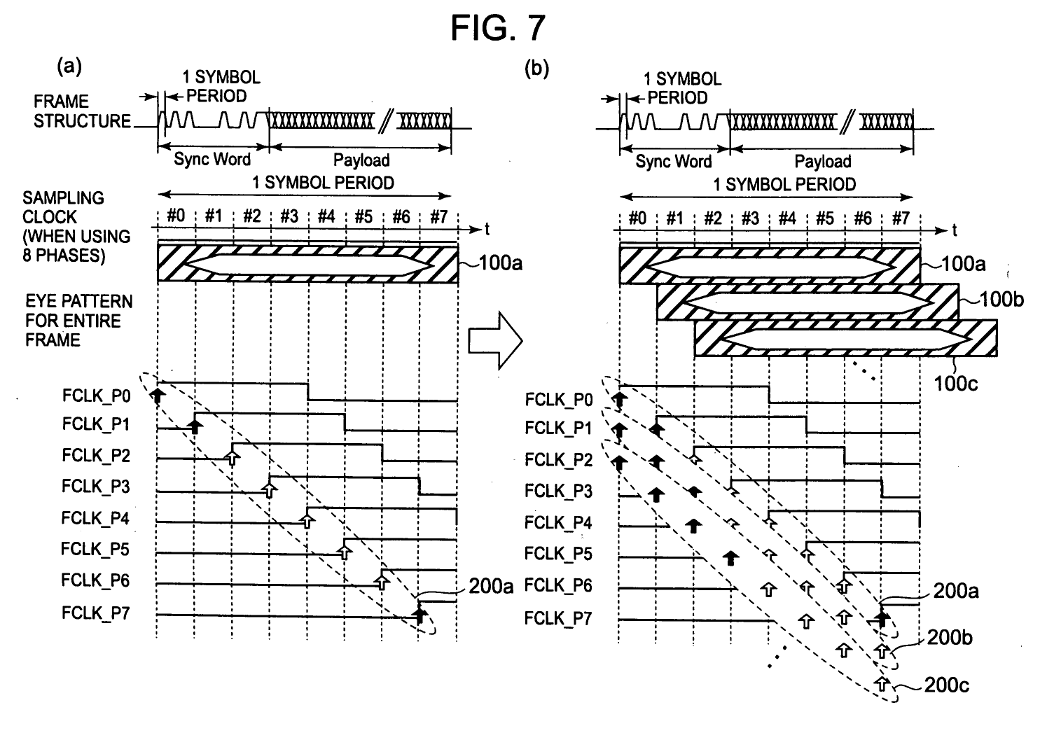

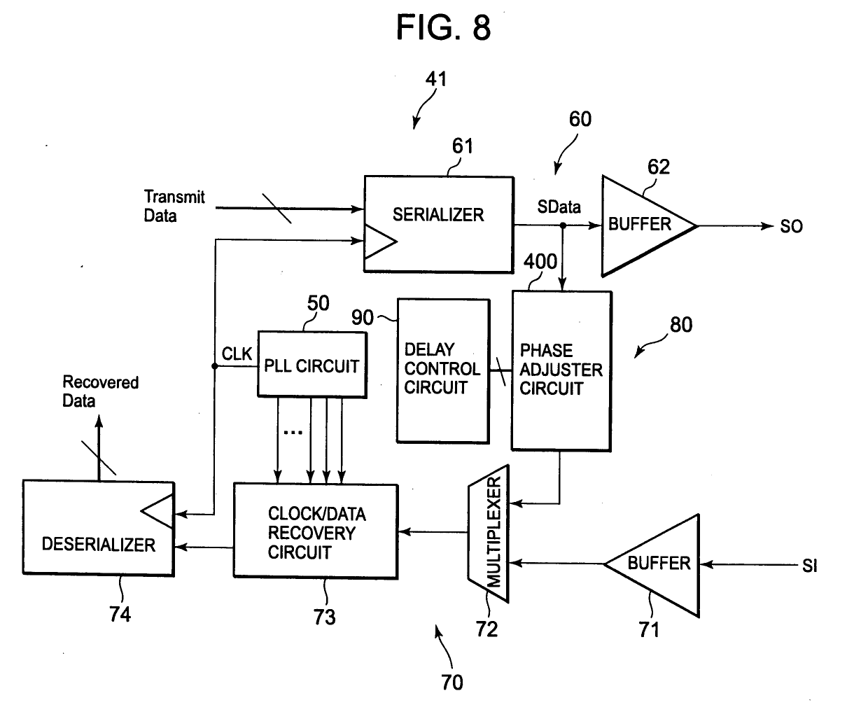

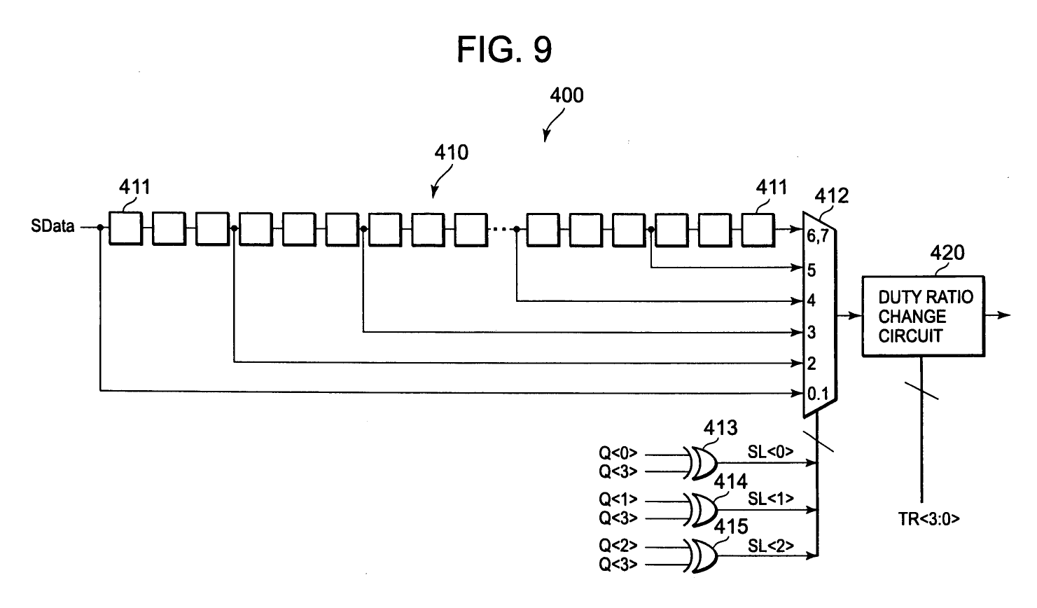

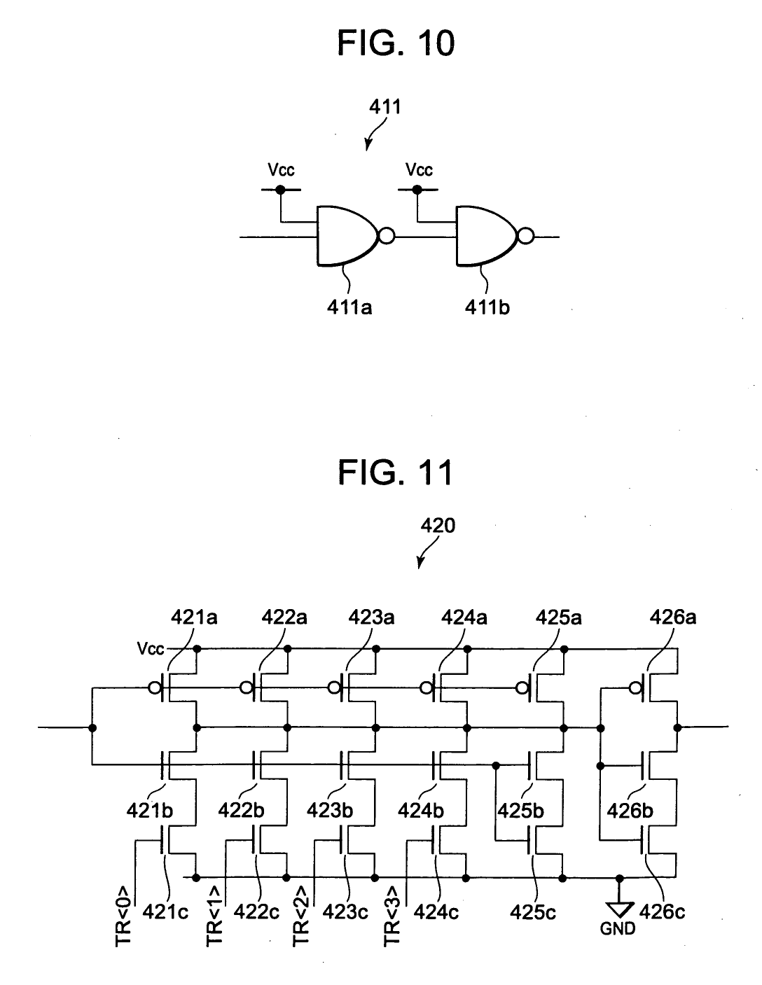

The effect of the present invention is described next in detail while referring to FIG. 7. Here, FIG. 7 is a drawing for describing the overall operation of the present invention. In the present invention the transmission signal is placed in a frame format as already described. The frame contains a synch word section and a payload section in the data string. Moreover, in this exemplary embodiment, the receive circuit (RX) 8 samples the transmission signal by utilizing a frequency that is eight times that of the symbol rate. Namely, the receive circuit (RX) 8 samples the transmission signal by utilizing 8 phase sampling clocks (Shown in this figure by #0 through #7.) for each symbol. The frame structure is not limited to the above structure, and any frame structure is sufficient provided there is a preamble for acquiring the synchronization, and data following the preamble.

The EYE pattern for the entire frame in FIG. 7 shows the tracks when all data signals contained in one frame are doubled-back and overlapped for each symbol. More specifically, when handling one symbol as one bit, each frame may for example be made up of 128 bits. Here, the time required for transmitting one symbol is 3.2 ns when the symbol transfer rate (symbol rate) was set to 312 MHz. The Eye pattern measurement device extracts a waveform every 3.2 ns equivalent to one symbol, for each symbol contained in the entire frame. The eye pattern for the entire frame can be observed by overlapping the waveforms for these 128 symbols. When there are fluctuations in the clock due to jitter, the sampled data will be affected in the same way. So when showing data signals as doubled-back and overlapped for each symbol, the jitter component from each symbol will successively accumulate and jitter components expanding to enclose the data change point will occur within the eye pattern for that entire frame. The jitter component where expansion is occurring along the entire eye pattern is shown by the oblique line portion in the figure.

In the process for receiving the transmission signal, the synchronization detector unit 21 in the receive circuit (RX) 8 of the present invention detects synchronization by utilizing the eight clocks FCLK_P0 through 7. Moreover, the synchronization detector unit 21 of receive circuit (RX) 8 identifies clocks where synchronization was detected as selected clock candidates. Next, the clock phase selector unit 22 of the receive circuit (RX) 8 selects one sampling clock for use in sampling transmission signals among the identified selected clock candidates. The clock handoff unit 23 of the receive circuit (RX) 8 then utilizes the eight clocks FCLK_P0 through 7 to carry out the clock handoff. The FIFO unit then uses the selected sampling clocks to sample the received signals.

FIG. 7A shows an example of the operation in a semiconductor integrated circuit of the background art when the transmit circuit (TX) 7 utilizes a fixed clock for sending the transmission signal. When the flip-flops in the final output of the transmit circuit (TX) 7 are operated by a clock having a fixed phase, then during loopback test operation, the Eye pattern 100a for the transmission signal contains symbol boundary jitter only for the fixed clock. So, when making an evaluation of the receive circuit (RX) in a state where the Eye pattern 100a is fixed as shown in FIG. 7(a), the center phase of the Eye pattern 100a is also constantly fixed, so that only the receive characteristics (phase selection algorithm) for these limited number of sampling clocks can be verified. In other words, only the clock combination shown in the area enclosed by the broken line 200a can be verified in the example shown in FIG. 7A. More specifically, the receive circuit (RX) 8 identifies clocks possessing a clock edge shown by the outline arrows as selected clock candidates. The receive circuit (RX) 8 then selects for example the clock FCLK_P4 from among the selected clock candidates as the single sampling clock for use in sampling the transmission signal.

More specifically, when making a loopback test during the semiconductor integrated circuit screening evaluation in a state where the transmission signal clock is the fixed clock, the circuits formed for each (and every) sampling clock (synchronization detector unit, clock handoff unit, etc.) are seen as unneeded paths and so not evaluated. However during actual usage after production, these paths of course are no longer unneeded paths and become regular circuit paths that were overlooked during the screening and therefore might cause glitches or malfunctions when marketed as products. In the clock handover processor unit for example, data acquired from circuits supplied with clocks other than the center phase of Eye pattern 100a is judged to have poor reliability, and the received data does not propagate to circuit in stages subsequent (downstream) of data selector 25 in FIFO unit 24. Also, when making screening evaluations in the FIFO unit 24 by applying expectation value judgments to parallel signals that were serial-parallel converted; those data lines not propagating to the FIFO unit 24 are not considered part of the evaluation. Moreover, in the clock phase selector 22, only limited timing decisions and phase select algorithm validity decisions can be made when there are no state transitions within combination circuits due to use of fixed input signals.

FIG. 7B shows an example of operation in the semiconductor integrated circuit 1 of the present invention. In the semiconductor integrated circuit 1 of the present invention, the clock utilized by the transmit (TX) circuit 7 to send the transmission signals is variable and therefore in contrast to conventional loopback tests that can only evaluate fixed phase waveforms 100a as shown in FIG. 7A; the present invention as shown in FIG. 7B is capable of evaluating even multiple phase waveforms (100100b, 100c, . . . ) and can inclusively verify the receive characteristics of all sampling clocks. The present invention can in other words, all-inclusively verify the clock combinations shown enclosed by the broken line section 200a, the clock combinations shown enclosed by the (broken line section) 200b, the clock combinations shown enclosed by the (broken line section) 200c, and so on.

The present invention is further not limited only to the above described exemplary embodiments and needless to say, all manner of changes and adaptations not departing from the scope of the present invention are allowable.

Further, it is noted that Applicant's intent is to encompass equivalents of all claim elements, even if amended later during prosecution.

What is claimed is:

1. A semiconductor integrated circuit comprising:
an oscillation circuit for generating multiple clocks with mutually different phases,
wherein a single clock is selected from the multiple clocks for use in sending a transmission signal, and the transmission signal is sent by utilizing the selected single clock.

2. The semiconductor integrated circuit according to claim 1, further comprising:
a transmit circuit to send the transmission signal; and
a receive circuit to receive the transmission signal sent from the transmit circuit during a loopback test,
wherein the receive circuit utilizes the multiple clocks to perform a receive processing.

3. The semiconductor integrated circuit according to claim 2,
wherein the transmit circuit includes a parallel-serial converter circuit to convert multiple bits of parallel data to serial data, and
wherein the transmit circuit sends the serial data as the transmission signal.

4. The semiconductor integrated circuit according to claim 3, further comprising:
a phase adjuster unit to select a single clock from the multiple clocks,
wherein the transmit circuit includes multiple parallel-serial converter circuits to operate in synchronization with each of the multiple clocks, and
wherein the transmit circuit sends the serial data output from the parallel-serial converter circuit corresponding to the single clock selected by the phase adjuster unit as the transmission signal.

5. The semiconductor integrated circuit according to claim 3, further comprising:
a phase adjuster unit to switch the single clock selected from the multiple clocks, to another clock,
wherein the parallel-serial converter circuit synchronizes with the another clock to which the phase adjuster unit switched and performs parallel-serial conversion.

6. The semiconductor integrated circuit according to claim 2,
wherein the transmit circuit sends the transmission signal as frames, and
wherein the receive circuit includes a synchronization detector unit to detect synchronization by receive processing that utilizes multiple clocks for the synchronized information contained in the frame during the loopback test, and also identifies the synch-detected clock as a selected candidate clock.

7. The semiconductor integrated circuit according to claim 6,
wherein the receive circuit further includes a clock handoff unit to receive data signals output by the synchronization detector unit at the multiple clocks, and convey the data signals received to a standard clock.

8. The semiconductor integrated circuit according to claim 2,
wherein a differential circuit connects the transmit circuit and the receive circuit and, during the loopback test, the transmission signals are sent and received by way of the differential circuit.

9. A test method for a semiconductor integrated circuit including an oscillation circuit to generate multiple clocks of mutually different phases, a transmit circuit to send a transmission signal, and a receive circuit to receive the transmission signal sent by the transmit circuit during a loopback test operation, the method comprising:
selecting a single clock from the multiple clocks for use in sending the transmission signal and, to send the transmission signal by utilizing the selected single clock; and
performing a receive processing by utilizing the multiple clocks.
